(19) United States
(12) Patent Application Publication
(10) Pub. No.: US 2017/0358446 A1
(43) Pub. Date: Dec. 14, 2017

(54) WAFER PROCESSING APPARATUS AND WAFER PROCESSING METHOD USING THE SAME

(71) Applicant: TAIWAN SEMICONDUCTOR MANUFACTURING CO., LTD., Hsinchu (TW)

(72) Inventors: Cheng-Yi WU, Taichung City (TW); Tzu-Shin Chen, Tainan City (TW); Che-Kang Liu, Tainan City (TW); Chi-Shun Wang, Tainan City (TW); Chin-Szu LEE, Taoyuan City (TW); Chia-Chun HUNG, Taichung City (TW); Li-Hsuan CHU, Taichung City (TW)

(21) Appl. No.: 15/180,255

(22) Filed: Jun. 13, 2016

(51) Int. Cl. H01L 21/02; G21K 5/08

(52) U.S. Cl. CPC H01L 21/02348; G21K 5/08

(57) ABSTRACT

A wafer processing apparatus includes at least one pedestal, at least one ultraviolet (UV) light source, and a window. The pedestal is configured to support a wafer. The UV light source is configured to generate UV radiation to the wafer. The window is present between the pedestal and the UV light source. The UV radiation is capable of passing through the window, and the window is a convex lens, a concave lens, or combinations thereof.

### BACKGROUND

As the semiconductor industry introduces new generations of integrated circuits (IC's) having higher performance and greater functionality, the density of the elements that form those IC's is increased, while the dimensions, sizes, and spacing between the individual components or elements are reduced. While in the past such reductions were limited by the ability to define the structures photo-lithographically, device geometries having smaller dimensions created new limiting factors. For example, for two adjacent conductive paths, as the distance between the conductors decreases, the resulting capacitance (a function of the dielectric constant (k) of the insulating material divided by the distance between conductive paths) increases. This increased capacitance results in increased capacitive coupling between the conductors, increased power consumption, and increased resistive-capacitive (RC) delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D are cross-sectional views of a method for manufacturing a semiconductor device at various stages in accordance with some embodiments of the present disclosure.

FIG. 2 is a schematic diagram of a wafer processing apparatus in accordance with some embodiments of the present disclosure.

FIG. 3 is a flowchart of a method for processing a wafer in accordance with some embodiments.

FIGS. 4A to 4G are cross-sectional views of the windows in accordance with some embodiments.

FIG. 5 is a schematic diagram of a wafer processing apparatus in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

UV curing has been employed to lower the k-value of dielectric materials such as oxides deposited by pulse deposition layer (PDL) processes. UV curing is used to drive out porogen from composite porogen-dielectric films, leaving a porous dielectric matrix with a low k-value between about 2.0 and about 2.6. Curing wafers takes place in a chamber filled with a gas. A wafer is placed in the chamber and exposed to UV radiation. The geometry of available UV radiation sources results in non-uniform irradiation of the wafer surface, thereby causing variations in the cure efficacy at various locations. Therefore, the embodiments of the present disclosure provide a wafer processing apparatus and a wafer processing method to provide uniform UV radiation on the wafer.

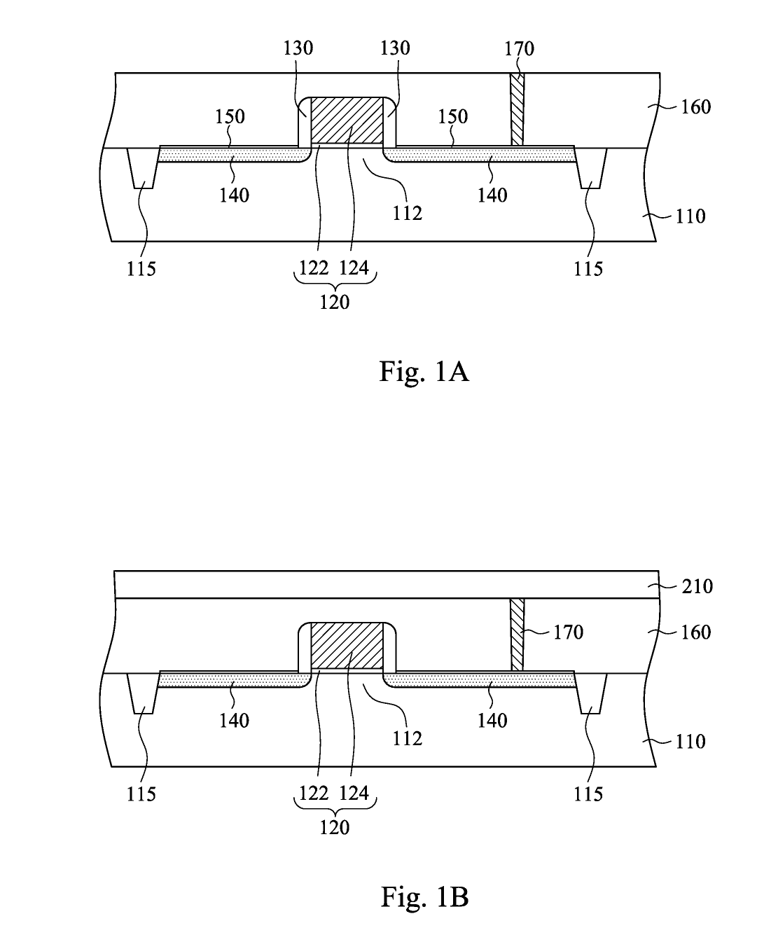

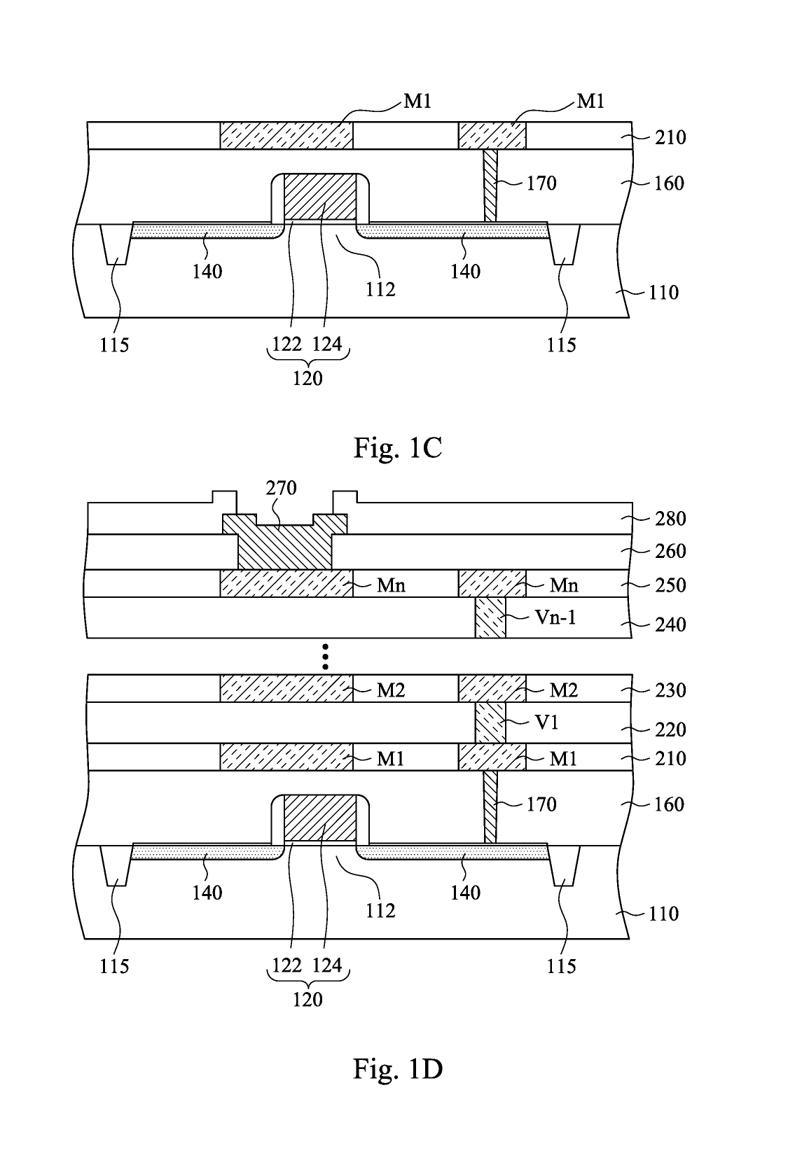

FIGS. 1A to 1D are cross-sectional views of a method for manufacturing a semiconductor device at various stages in accordance with some embodiments of the present disclosure. Reference is made to FIG. 1A. A substrate 110 is provided. In some embodiments, the substrate 110 may include silicon (Si). Alternatively, the substrate 110 may include germanium (Ge), silicon germanium, gallium arsenide (GaAs) or other appropriate semiconductor materials. Also alternatively, the substrate 110 may include an epitaxial layer. For example, the substrate 110 may have an epitaxial layer overlying a bulk semiconductor. Further, the substrate 110 may be strained for performance enhancement. For example, the epitaxial layer may include a semiconductor material different from those of the bulk semiconductor such as a layer of silicon germanium overlying a bulk silicon or a layer of silicon overlying a bulk silicon germanium formed by a process including selective epitaxial growth (SEG). Furthermore, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or other appropriate method. In various embodiments may include any of a variety of substrate structures and material.

The substrate 110 also includes various doped regions formed by implantation techniques. For example, a portion of the substrate 110 is doped to form a P-well (not shown) where an n-channel device will be fabricated. Similarly, another portion of the substrate 110 can be doped to form an N-well (not shown) where a p-channel device will be fabricated. The doped wells are doped with P-type dopants, such as boron or BF₂, and/or N-type dopants, such as phosphorus or arsenic. The doped wells may be formed directly on the substrate 110 or using a raised structure.

The substrate 110 also includes various isolation features 115, such as shallow trench isolation (STI), formed in the substrate 110 to separate various devices. The formation of the STI may include etching a trench in the substrate 110, filling the trench by dielectric materials such as silicon oxide, silicon nitride, or silicon oxynitride and using chemical mechanical polishing (CMP) to remove the excessive dielectric metals layers. The filled trench may have a multi-layer structure such as a thermal oxide liner layer with silicon nitride filling the trench. In greater detail, the isolation features 115 may be created using a process sequence such as: growing a pad oxide, forming a low pressure chemical vapor deposition (LPCVD) nitride layer, patterning an opening by using photoresist and masking, etching a trench in the substrate 110, optionally growing a thermal oxide trench liner to improve the trench interface, filling the trench with CVD oxide, and using chemical mechanical planarization (CMP) to remove the excessive dielectric layers.

In FIG. 1A, at least one gate stack 120 including a gate dielectric 122 and a gate electrode 124 is formed on the substrate 110. In some embodiments, in order to form the gate stack 120, a gate dielectric layer is formed on the substrate 110, followed by a gate electrode layer. The gate dielectric layer and the gate electrode layer are then patterned, forming the gate dielectric 122 and the gate electrode 124, respectively. Hard masks (not shown) may be formed on the gate stack 120 for process reasons, wherein the hard masks may include silicon nitride.

The gate dielectric 122 may include various materials such as a silicon oxide, a silicon nitride, or a silicon oxynitride. Alternatively, the gate dielectric 122 may have high dielectric constant (HK) values. In some embodiments, the gate dielectrics 122 include HfO₂. Alternatively, the gate dielectric 122 may include HfSiO, HfSiON, HfTaO, HfTiO, HfZrO, zirconium oxide, aluminum oxide, hafnium dioxide-alumina (HfO₂—Al₂O₃) alloy, other suitable HK dielectric materials, or combinations thereof. The gate dielectric 122 can be formed by a suitable process such as atomic layer deposition (ALD). Other methods to form the gate dielectric 122 include metal organic chemical vapor deposition (MOCVD), physical vapor deposition (PVD), UV-Ozone Oxidation, or molecular beam epitaxy (MBE). The gate electrode 124 can be made of polysilicon or other suitable materials.

A plurality of gate spacers 130 are formed on sidewalls of the gate stack 120. The gate spacer 130 may include a seal spacer and a main spacer. The gate spacers 130 include one or more dielectric materials, such as silicon oxide, silicon nitride, silicon oxynitride, or combinations thereof. The seal spacers are formed on sidewalls of the gate stack 120 and the main spacers are formed on the seal spacers. In some embodiments, the gate spacers 130 include additional layers. For example, a dielectric layer (not shown) is formed on the seal spacer and then the main spacer is formed on the dielectric layer. In some embodiments, the seal spacer includes silicon nitride, the dielectric layer includes silicon oxide, and the main spacer includes silicon nitride. The seal spacers, the main spacers, and the dielectric layer are formed by deposition, photolithography, and etch processes in a known manner.

In some embodiments, a replacement gate (RPG) process scheme is employed. In a RPG process scheme, a dummy polysilicon gate is formed first and is replaced later by a metal gate after high thermal budget processes are performed. That is, the gate electrode 124 is a metal gate. The metal gate may include gate dielectric layer(s), capping layer(s), fill layer(s), and/or other suitable layers that are desirable in a metal gate stack. The metal gate may be deposited by ALD, PVD, CVD, or other suitable process.

A plurality of source and drain (S/D) regions 140 are formed by a suitable technique, such as one or more ion implantations. The two S/D regions 140 define a channel region 112 beneath the gate stack 120. In some embodiments, silicide features 150 may be further formed on the S/D regions 140 to reduce the contact resistance. The silicide features 150 may be formed by a technique referred to as self-aligned silicide (salicide) including metal deposition (such as nickel deposition) onto the substrate 110, a thermal anneal to react the metal with silicon to form silicide (NiSi), and an etch to removed un-reacted metal. In some embodiments, the S/D regions 140 may further include lightly doped (LDD) regions substantially aligned with the seal spacer and a heavily doped regions substantially aligned with the main spacers.

In some other embodiments, the S/D regions 140 may include epitaxially grown semiconductor material for proper strain effect, leading to enhanced carrier mobility in the channel 112. In some embodiments, the silicide features 150 are epitaxially grown in the S/D regions 130 for a field effect transistor (FET). The method to form the strained structure includes etching to form recesses in the substrate 110 and epitaxially growth to form crystalline a semiconductor material in the recesses.

A dielectric layer 160 is then formed on the substrate 110 and the gate stack 120. The dielectric layer 160 can be an inter-layer (or inter-level) dielectric (ILD) layer. The dielectric layer 160 may be formed by chemical vapor deposition (CVD), high-density plasma CVD, spin-on, sputtering, or other suitable methods. In some embodiments, the dielectric layer 160 includes silicon oxide. In some other embodiments, the dielectric layer 160 may include silicon oxy-nitride, silicon nitride, or a low-k material.

At least one conductive feature 170 is formed in the dielectric layer 160. The conductive feature 170 is a metal contact in FIG. 1A. That is, the conductive feature 170 and the dielectric layer 160 form a metal-dielectric (MD) layer. The conductive feature 170 is connected to the silicide feature 150 to be electrically connected to the S/D regions 140. In some embodiments, metal materials can be filled in the through hole of the dielectric layer 160, and the excessive portions of the metal materials are removed by performing a CMP process to form the conductive feature 170. The conductive feature 170 can be made of tungsten, aluminum, copper, or other suitable materials. The conductive feature 170 may also have composite structures, including, e.g., barrier and adhesion layers, such as titanium/titanium nitride or tantalum nitride, and other layers as well.

Reference is made to FIG. 1B. Another dielectric layer 210 is formed on the dielectric layer 160 and the conductive feature 170. In some embodiments, the dielectric layer 210 includes a low dielectric constant (low-k) dielectric material. The dielectric constant of the low-k dielectric material may be about 2.7 to about 3.0. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, Xerogel, Aerogel, amorphous fluorinated carbon, Parylene, bis-benxocyclocutenes (BCB), polyimide, polynoroboneses, benzocyclocutene, PTFE, hydrogen silsesquioxane (HSQ), methylsilsesquioxane (MSQ), and/or combinations thereof. The low-k dielectric material may be deposited by a chemical vapor deposition (CVD), plasma enhanced CVD (PECVD), or spin-on process.

In addition, the low-k dielectric may include one or more additives. The additive may be used to increase the carbon content of the final low-k dielectric material from that which it would have had if including the low-k dielectric and/or porogen. The additive may also increase the mechanical strength or hardness of the final low-k dielectric material from that which it would have had if including the low-k dielectric and/or the porogen. After a low-k dielectric film containing the porogen is deposited on the substrate 110, the film may need to be cured to create pores in the low-k dielectric film and to remove the porogen or to convert the porogen into part of the low-k dielectric, in accordance with some embodiments. The low-k dielectric film containing the porogen before the porogen is converted is dense and without pores. In some embodiments, the dense low-k dielectric film undergoes a ultra-violet (UV) curing process to convert the porogen. The curing could be performed in a furnace or by other processes, such as heating, rapid thermal curing, flash curing, laser curing, etc.

UV curing is an effective way of converting the porogen into part of the low-k dielectric. The curing may be performed in an environment with hydrogen, such as pure hydrogen or hydrogen with an inert gas, to prevent the oxidation of metal layer(s) exposed or covered by the low-k dielectric layer. For example, the curing may be a UV curing, performed at a temperature in a range from about 300° C. to about 400° C. The curing time depends on the thickness of the dense low-k dielectric layer. For example, a dense low-k dielectric film with a thickness in a range from about 50 nm to about 350 nm may be cured for a period in a range from about 1 minute to about 30 minutes.

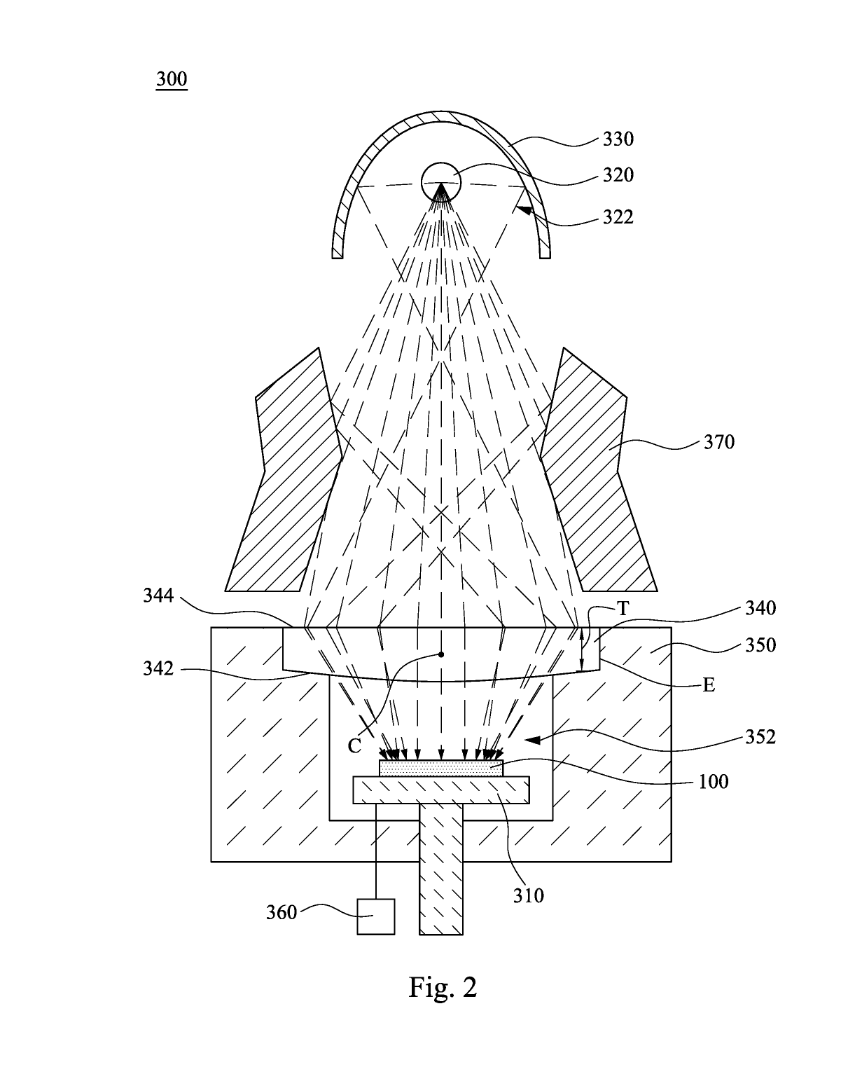

FIG. 2 is a schematic diagram of a wafer processing apparatus in accordance with some embodiments of the present disclosure. The structure of FIG. 1B (as referred as a wafer 100 hereinafter) can be UV cured in the wafer processing apparatus. The wafer processing apparatus includes at least one pedestal 310, at least one ultraviolet (UV) light source 320, a primary reflector 330, and a window 340. The pedestal 310 is configured to support the wafer 100. The UV light source 320 is present on the pedestal 310 and is configured to generate UV radiation 322 to the wafer 100. The primary reflector 330 partially surrounds the UV light source 320. The window 340 is present between the pedestal 310 and the UV light source 320. The UV radiation 322 is capable of passing through the window 340, and the window 340 is a convex lens, a concave lens, or combinations thereof. In other words, the window 340 has a first surface 342 facing the pedestal 310 and a second surface 344 facing the UV light source 320. At least one of the first surface 342 and the second surface 344 of the window 340 is a curved surface. The first surface 342 and the second surface 344 of the window 340 are non-parallel. Hence, the thickness T of the window 340 varies from the center C of the window 340 to an edge E of the window 340. For example, the window 340 in FIG. 2 is a convex lens. The first surface 342 of the window 340 is a curved surface that is curved outwardly, and the second surface 344 of the window 340 is a substantially flat surface. The thickness T of the window 340 is reduced from the center C of the window 340 to the edge E of the window 340. The terms ‘substantially’ as used herein may be applied to modify any quantitative representation which could permissibly vary without resulting in a change in the basic function to which it is related.

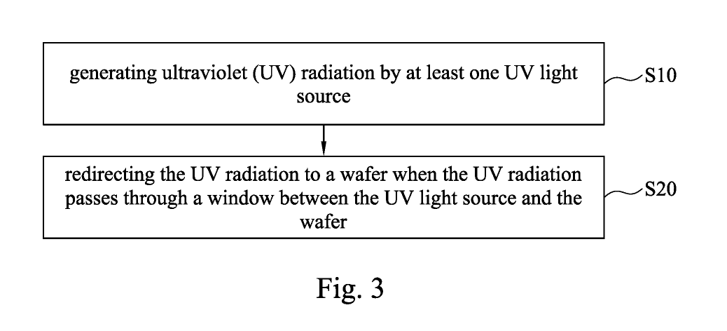

FIG. 3 is a flowchart of a method for processing the wafer 100 in accordance with some embodiments. Reference is made to FIGS. 2 and 3. The wafer 100 is provided into the wafer processing apparatus. The wafer 100 is disposed on the pedestal 310 and faces the UV light source 320. As shown in operation S10, the UV radiation 322 is generated by at least one UV light source 320. In greater detail, the UV radiation 322 is guided at least by the primary reflector 330, passes through the window 340, and impinges on the wafer 100. The dielectric layer 210 of the wafer 100 of FIG. 1B is cured to leave pores therein. Hence, the dielectric layer 210 becomes an extreme low-k dielectric layer, whose dielectric constant may be about 2.0 to about 2.6.

As shown in operation S20, the UV radiation 322 is redirected when the UV radiation 322 passes through the window 340 between the UV light source 320 and the wafer 100. The window 340 is present substantially above the pedestal 310 to permit radiation of the wafer 100 with UV output of the desired wavelengths from UV light source 320. The window 340 of FIG. 2 is a convex lens, which can focus the UV radiation 322 to the wafer 100. Hence, the UV radiation 322 can be redirected to form a substantially uniform distribution of the UV radiation 322 on the wafer 100. With such configuration, the k-value of the cured dielectric layer 210 has more uniform distribution. As such, the electrical properties (such as RC delay) of the semiconductor device can be improved.

In some embodiments, the window 340 is made of quartz glass and has sufficient thickness to maintain vacuum without cracking. In some other embodiments, the window 340 is fused silica. In some embodiments, the wafer processing apparatus further includes a chamber housing 350 connected to the window 340 and configured to fix the window 340. The chamber housing 350 forms an accommodating space 352 for accommodating the pedestal 310 and the wafer 100. The wafer 100 is cured in the accommodating space 352 of the chamber housing 350.

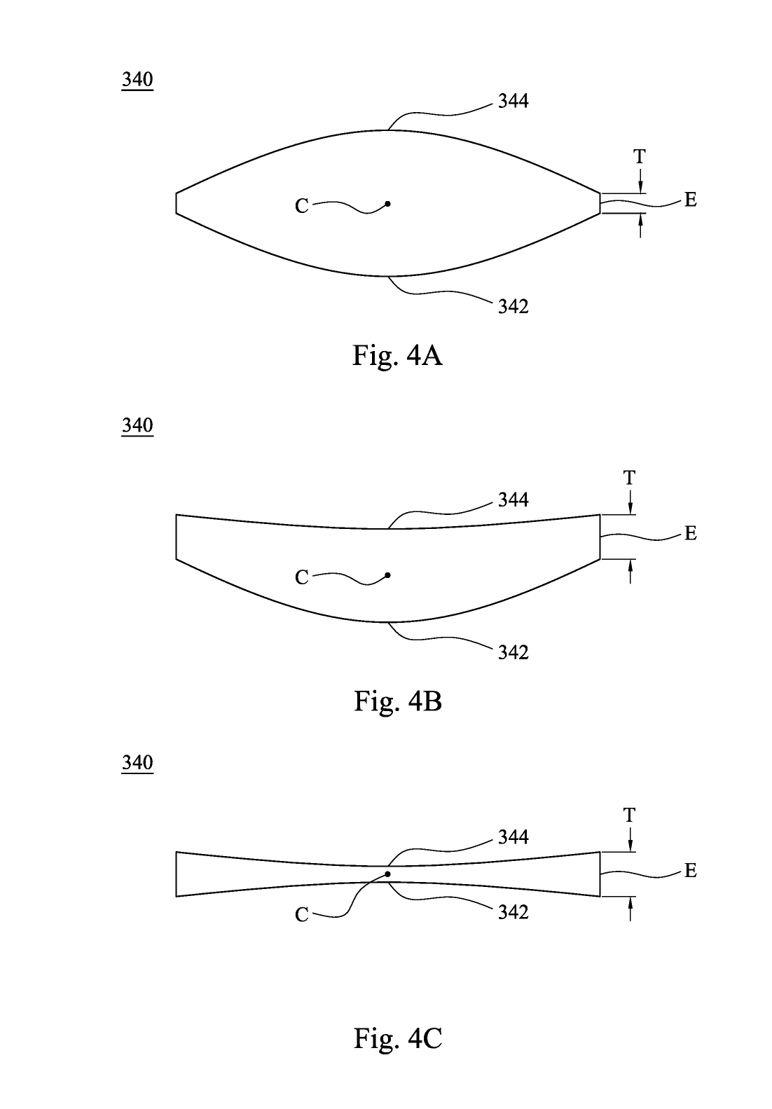

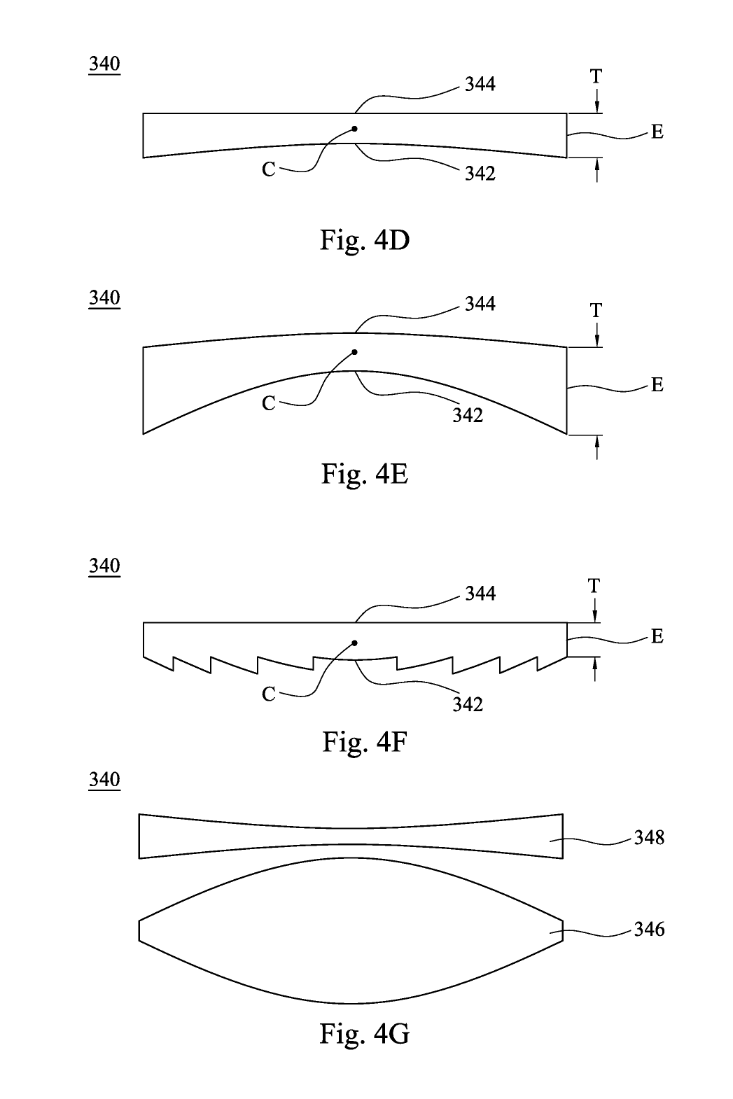

However, the structure of the window is not limited with this regard. FIGS. 4A to 4G are cross-sectional views of the window 340 in accordance with some embodiments. In FIG. 4A, the window 340 is a convex lens. The first surface 342 and the second surface 344 of the window 340 are both convex surfaces. In FIG. 4B, the window 340 is a convex lens. The first surface 342 of the window 340 is a convex surface and the second surface 344 of the windows 340 is a concave surface. The thickness T of the window 340 in FIGS. 4A or 4B is reduced from the center C of the window 340 to the edge E of the window 340. The windows 340 in FIGS. 4A and 4B can focus the UV radiation 322 (see FIG. 2). In FIG. 4C, the window 340 is a concave lens. The first surface 342 and the second surface 344 of the window 340 are both concave surfaces. In FIG. 4D, the window 340 is a concave lens. The first surface 342 of the window 340 is a concave surface and the second surface 344 of the windows 340 is a substantially flat surface. In FIG. 4E, the window 340 is a concave lens. The first surface 342 of the window 340 is a concave surface and the second surface 344 of the windows 340 is a convex surface. The thickness T of the window 340 in FIG. 4C, 4D, or 4E is increased from the center C of the window 340 to the edge E of the window 340. The windows 340 in FIGS. 4C, 4D, and 4E can diverge the UV radiation 322 (see FIG. 2). In FIG. 4F, the window 340 is a Fresnel lens. The first surface 342 of the window 340 is a curved surface and the second surface 344 of the windows 340 is a substantially flat surface. The thickness T of the window 340 in FIG. 4F is varied from the center C of the window 340 to the edge E of the window 340. In FIG. 4G, the window 340 is a combination of a convex lens 346 and a concave lens 348.

Reference is made to FIG. 2. In some embodiments, the UV light source 320 is a UV lamp (such as a high power mercury microwave lamp, pulsed xenon flash lamps, or high-efficiency UV light emitting diode arrays) having an elongated UV bulb. The UV bulb is sealed plasma bulbs filled with one or more gases such as xenon (Xe) or mercury (Hg) for excitation by power sources (not shown). In some embodiments, the power sources are microwave generators that can include at least one magnetron (not shown) and at least one transformer (not shown) to energize filaments of the magnetrons. In some other embodiments, the UV bulb can include an electrode or filament therein such that the power sources represent circuitry and/or current supplies, such as direct current (DC) or pulsed DC, to the electrode.

The primary reflector 330 partially surrounds the UV light source 320. The primary reflector 330 has a reflective surface that may be a parabolic surface, an elliptical surface, freeform surface, or combinations thereof. The primary reflector 330 can guide the UV radiation 322 generated from the UV light source 320 to the wafer 100.

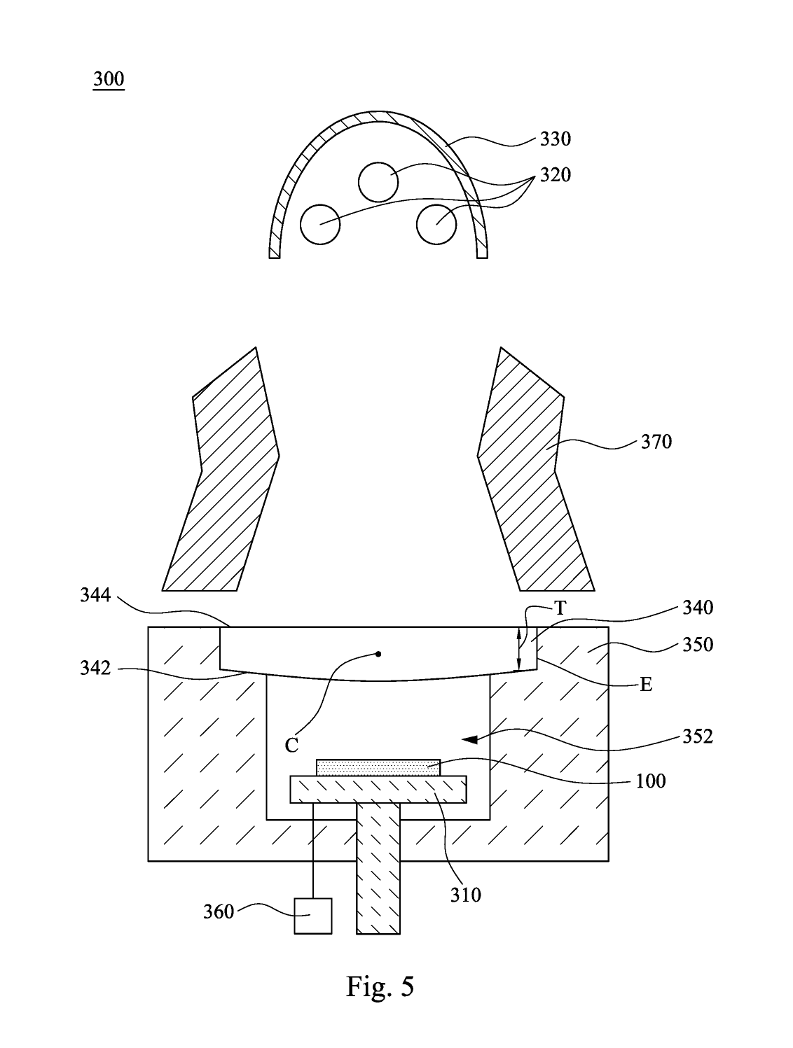

FIG. 5 is a schematic diagram of a wafer processing apparatus in accordance with some embodiments of the present disclosure. In FIG. 5, the wafer processing apparatus includes a plurality of UV light sources 320. The UV light sources 320 are partially surrounded by the primary reflector 330. With this configuration, the intensity of the UV radiation incident the wafer 100 can be increased, and further uniform. Other relevant structural details of the wafer processing apparatus in FIG. 5 are similar to the wafer processing apparatus of FIG. 2, and, therefore, a description in this regard will not be repeated hereinafter.

Reference is made to FIG. 2. The pedestal 310 can be made of ceramic or metal such as aluminum. In some embodiments, the wafer processing apparatus further includes a motion mechanism 360 connected to the pedestal 310 to move the pedestal 310. During the UV curing process, the motion mechanism 360 can move the pedestal 310, such that the UV radiation 322 can illuminate every portion of the wafer 100 to improve the k-value uniformity of the dielectric layer 210 (see FIG. 1B) of the wafer 100.

In some embodiments, the wafer processing apparatus further includes a secondary reflector 370 present between the primary reflector 330 and the window 340. The secondary reflector 370 can reflect the UV radiation 322 that would otherwise fall outside the boundary of the primary reflector 330 so that such radiation illuminates upon the wafer 100 being treated thus increasing the intensity of the energy distributed to the wafer 100. In some embodiments, the secondary reflector 370 can alter the pattern of the UV radiation 322 from a substantially rectangular shape to a substantially circular shape that corresponds to the substantially circular wafer 100 being exposed.

Reference is made to FIG. 1C. At least one trench 212 is formed in the cured dielectric layer 210, and at least one metal line M1 is formed in the trench 212 of the cured dielectric layer 210. The metal line M1 is used to interconnect the semiconductor device. Metal line M1 may be made of copper or copper alloys. The metal line M1 is formed by depositing a thin layer of seed copper or copper alloy, then plating to fill the trench 212 of the cured dielectric layer 210. A chemical mechanical planarization (CMP) is then performed to polish the copper to the surface of the trench 212.

Reference is made to FIG. 1D. At least one dual damascene process is performed to form a plurality of vias V1, . . . , Vn-1 and a plurality of upper-layer metal lines M2, . . . , Mn. The vias V1, . . . , Vn-1 and the upper-layer metal lines M2, . . . , Mn may be formed in different dielectric layers 220, 230, 240, and 250. Semiconductor device of FIG. 1D may include ten metallization layers, or even more. In some embodiments, at least one of the dielectric layers 220, 230, 240, and 250 is made of ELK dielectric material and is performed the aforementioned UV curing process. Some other dielectric layers 220, 230, 240, and 250 may be low-k dielectric layers or undoped silicate glass (USG) layers.

At least one metal pad 270 is formed on top of the metal line Mn and is exposed through passivation layers 260 and 280. The metal pad 270 and the passivation layer 260, 280 are in combination referred to as a top metallization layer. The passivation layers 260 and 280 may include dielectric materials such as un-doped silicate glass (USG), oxides, nitrides, or the like, and may have a k value greater than that of the underlying low-k dielectric layers. In some embodiments, the passivation layers 260 and 280 have k values of greater than about 3.0. The metal pad 270 is electrically connected to other portions of the semiconductor device through the metal lines, vias, and redistribution traces (not shown).

According to some embodiments, the dielectric layer of the semiconductor device can be UV cured to lower the k-value thereof. The window of the wafer processing apparatus can redirect the UV radiation, improving the uniformity of the UV radiation on the wafer. With such configuration, the cured dielectric layer can have a uniform k-value distribution over the whole wafer. Hence, the electrical properties (such as RC delay) of the semiconductor device can be improved.

According to some embodiments, a wafer processing apparatus includes at least one pedestal, at least one ultraviolet (UV) light source, and a window. The pedestal is configured to support a wafer. The UV light source is configured to generate UV radiation to the wafer. The window is present between the pedestal and the UV light source. The UV radiation is capable of passing through the window, and the window is a convex lens, a concave lens, or combinations thereof.

According to some embodiments, a wafer processing apparatus includes at least one pedestal, at least one ultraviolet (UV) light source, and a window. The pedestal is configured to support a wafer. The UV light source is configured to generate UV radiation to the wafer. The window is present between the pedestal and the UV light source. The UV radiation is capable of passing through the window. The window has a first surface facing the pedestal and a second surface facing the UV light source. At least one of the first surface and the second surface of the window is a curved surface.

According to some embodiments, a method for processing a wafer includes generating ultraviolet (UV) radiation by at least one UV light source. The UV radiation is redirected to the wafer when the UV radiation passes through a window between the UV light source and the wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-7. (canceled)

8. A wafer processing apparatus comprising:
at least one pedestal configured to support a wafer;
at least one ultraviolet (UV) light source configured to generate UV radiation to the wafer; and
a window present between the pedestal and the UV light source, wherein the UV radiation is capable of passing through the window, the window has a first surface facing the pedestal and a second surface facing the UV light source, and at least one of the first surface and the second surface of the window is a curved surface.

9. The wafer processing apparatus of claim 8, wherein a thickness of the window varies from a center of the window to an edge of the window.

10. The wafer processing apparatus of claim 8, wherein the first surface and the second surface of the window are non-parallel.

11. The wafer processing apparatus of claim 8, wherein the first surface of the window is a convex surface.

12. The wafer processing apparatus of claim 8, wherein the first surface of the window is a concave surface.

13. The wafer processing apparatus of claim 8, wherein the second surface of the window is a convex surface.

14. The wafer processing apparatus of claim 8, wherein the second surface of the window is a concave surface.

15. The wafer processing apparatus of claim 8, further comprising a primary reflector partially surrounding the UV light source.

16-20. (canceled)

21. A wafer processing apparatus comprising:
a chamber housing configured to accommodating a wafer;
at least one ultraviolet (UV) light source configured to generate UV radiation to the wafer; and
a window fixed on the chamber housing, wherein the UV radiation is capable of passing through the window into the chamber housing, the window has a top surface facing the UV light source and a bottom surface opposite to the top surface, and the top surface of the window is a curved surface.

22. The wafer processing apparatus of claim 21, further comprising a pedestal disposed in the chamber housing configured to supporting the wafer.

23. The wafer processing apparatus of claim 22, further comprising a motion mechanism connected to the pedestal to move the pedestal.

24. The wafer processing apparatus of claim 21, further comprising a primary reflector partially surrounding the UV light source.

25. The wafer processing apparatus of claim 24, wherein the primary reflector partially surrounds a plurality of the UV light sources.

26. The wafer processing apparatus of claim 24, further comprising a secondary reflector between the primary reflector and the chamber housing.

27. The wafer processing apparatus of claim 21, wherein the window is a Fresnel lens.

28. A wafer processing apparatus comprising:
a chamber housing configured to accommodating a wafer;
an ultraviolet (UV) light source configured to generate UV radiation to the wafer; and
a window fixed on the chamber housing, wherein the UV radiation is capable of passing through the window into the chamber housing, the window has a top surface facing the UV light source and a bottom surface opposite to the top surface, and the bottom surface of the window is a curved surface.

29. The wafer processing apparatus of claim 28, wherein a thickness of the window varies from a center of the window to an edge of the window.

30. The wafer processing apparatus of claim 28, wherein the top surface and the bottom surface of the window are non-parallel.

31. The wafer processing apparatus of claim 28, wherein the bottom surface of the window is a convex surface.

32. The wafer processing apparatus of claim 28, wherein the bottom surface of the window is a concave surface.
